(19) United States
(12) Patent Application Publication
(10) Pub. No.: US 2006/0018086 A1
(43) Pub. Date: Jan. 26, 2006

(54) Mechanism for fastening adapter card on expansion slot

(76) Inventor: Chin-Ching Liu, Shu-Lin City (TW)

Correspondence Address: TROXELL LAW OFFICE PLLC, SUITE 1404, 5205 LEESBURG PIKE, FALLS CHURCH, VA, 22041, US

(21) Appl. No.: 10/895,043

(22) Filed: Jul. 21, 2004

(51) Int. Cl. G06F 1/16; H05K 5/00; H05K 7/16

(52) U.S. Cl. 361/679; 361/727

(57) ABSTRACT

An expansion slot mounted on a motherboard of a microcomputer for electrically coupling to an inserted adapter card is disclosed. Inserting the adapter card into the expansion slot will flex a flexible member until a protrusion enters into a hole of the adapter card for fastening. Flexing a latch away from a second stop member will disengage the protrusion from the hole wherein the flexing of the latch is defined by contacting a bent member with a first stop member. Flexing the latch toward the second stop member will be stopped when the protrusion contacts the second stop member.

### FIELD OF THE INVENTION

The present invention relates to computer component connectors and more particularly to an improved mechanism for reliably fastening an adapter card inserted into an expansion slot on a motherboard of microcomputer.

### BACKGROUND OF THE INVENTION

Conventionally, an adapter card (e.g., AGP card) is added to a motherboard of microcomputer for providing additional functions. In detail, the adapter card is inserted into an expansion slot and is fastened by a fastening mechanism of the connector.

A conventional such fastening configuration is shown in FIGS. 1A and 1B. A connector and expansion slot combination 1 comprises an elongated expansion slot 3 mounted on the motherboard, and a connector 4 including an elongated channel 5 snugly fitted onto the expansion slot 3, a connecting member 6 provided at one end of the channel 5, a flexible member 7 extended outwardly from the connecting member 6, a tab 11 provided on the flexible member 7, and a fastening mechanism 8 provided at the other end of the channel 5 and including a fastening member 9 and a mated fastening member 10.

For mounting an adapter card 2, first disengage the fastening member 9 from the mated fastening member 10. Next, put the connector 4 onto the expansion slot 3. Next, engage the fastening member 9 with the mated fastening member 10. Finally, insert the adapter card 2 into the expansion slot 3 until both ends of the adapter card 2 are secured by the tab 11 and the fastening mechanism 8.

However, the prior art suffered from several disadvantages. For example, the connecting member 6 and/or the fastening member 9 may be broken if an excessive force is exerted on the connector 4 in the fastening process. Further, the mounting of the connector 4 onto the expansion slot 3 is interfered by other components on the motherboard due to the elongated shape of the connector 4. Hence, a need for improvement exists.

### SUMMARY OF THE INVENTION

It is an object of the present invention to provide an assembly for fastening an adapter card on a motherboard of a microcomputer, comprising an elongated expansion slot mounted on the motherboard and comprising, at one end thereof, an internal positioning member, a downwardly extended peg, a first recess, and an opposite second recess; and a fastening mechanism comprising a first guide member provided at one end, a second guide member opposite the first guide member wherein both the first and the second guide members are matingly fastened in the first and the second recesses respectively, a support with both the first and the second guide members formed thereon, a longitudinal slit defined by the first and the second guide members for securely receiving the peg, a mated positioning member provided on an inner surface of the first guide member fastened at the positioning member, an upper flexible member, a bent member extended from the flexible member, a latch formed at an open end of the flexible member, an upright first stop member spaced from the bent member, a transverse second stop member parallel with the flexible member, and a protrusion formed on a side of the flexible member spaced from the second stop member; whereby inserting the adapter card into the expansion slot will flex the flexible member until the protrusion enters into a hole of the adapter card for fastening; flexing the latch away from the second stop member will disengage the protrusion from the hole wherein the flexing of the latch is defined by contacting the bent member with the first stop member; and flexing the latch toward the second stop member will be stopped when the protrusion contacts the second stop member.

In one aspect of the present invention, the mated positioning member is a hook and the positioning member is a projection.

In another aspect of the present invention, the protrusion is a wedge.

The above and other objects, features and advantages of the present invention will become apparent from the following detailed description taken with the accompanying drawings.

### BRIEF DESCRIPTION OF THE DRAWINGS

FIG. 1A is an exploded view of a conventional configuration of fastening an adapter card in an expansion slot by means of the fastening mechanism of a connector;

FIG. 1B is a side view in part section showing the fastened adapter card in the expansion slot;

FIGS. 2A and 2B are top and front views of an expansion slot and a fastening mechanism fastened together according to a preferred embodiment of the invention respectively;

FIG. 2C is a sectional view taken along line 2C-2C of FIG. 2A;

FIGS. 3A, 3B, and 3C are top, front, and side views of the expansion slot shown in FIG. 2A;

FIGS. 4A and 4B are perspective and side views of the fastening mechanism shown in FIG. 2A;

FIG. 5 is a front view of the adapter card inserted into the expansion slot being fastened by the fastening mechanism according to the invention; and

FIGS. 6A and 6B are top views showing an excessive flexing of flexible member being stopped by first and second stop members respectively.

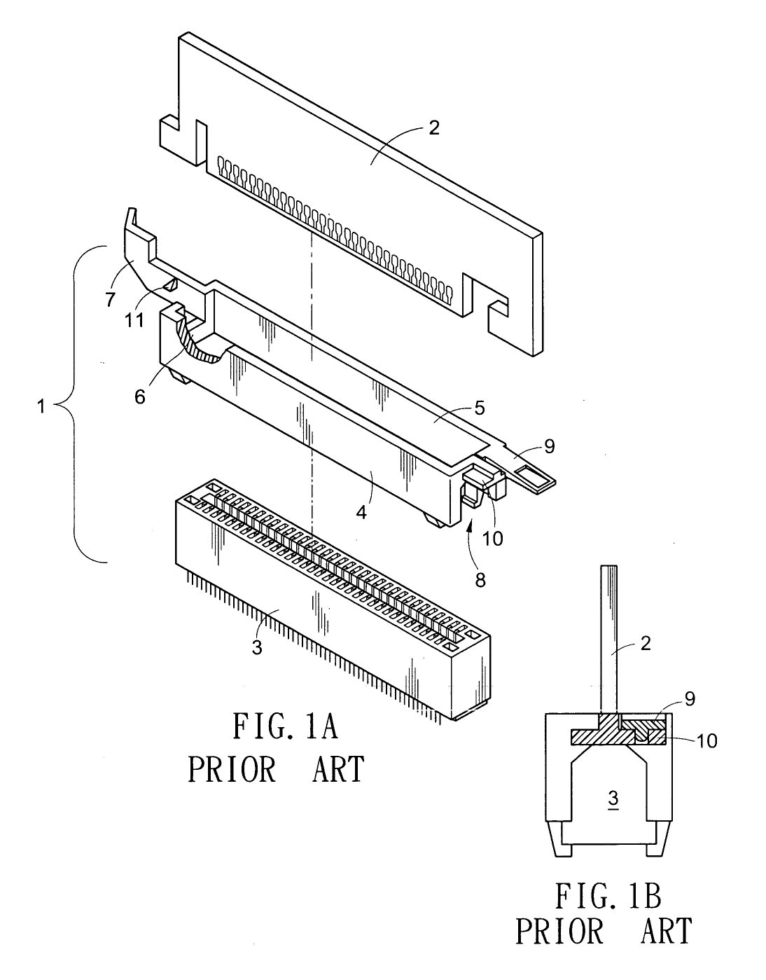

### DETAILED DESCRIPTION OF THE PREFERRED EMBODIMENTS

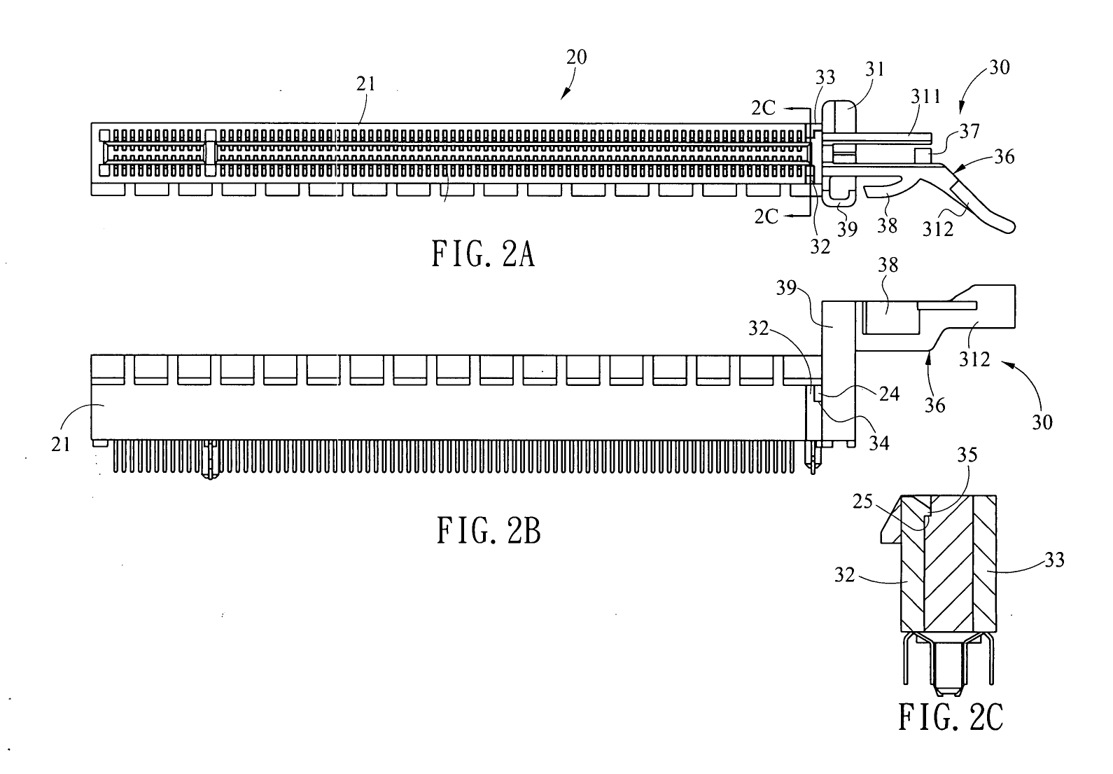

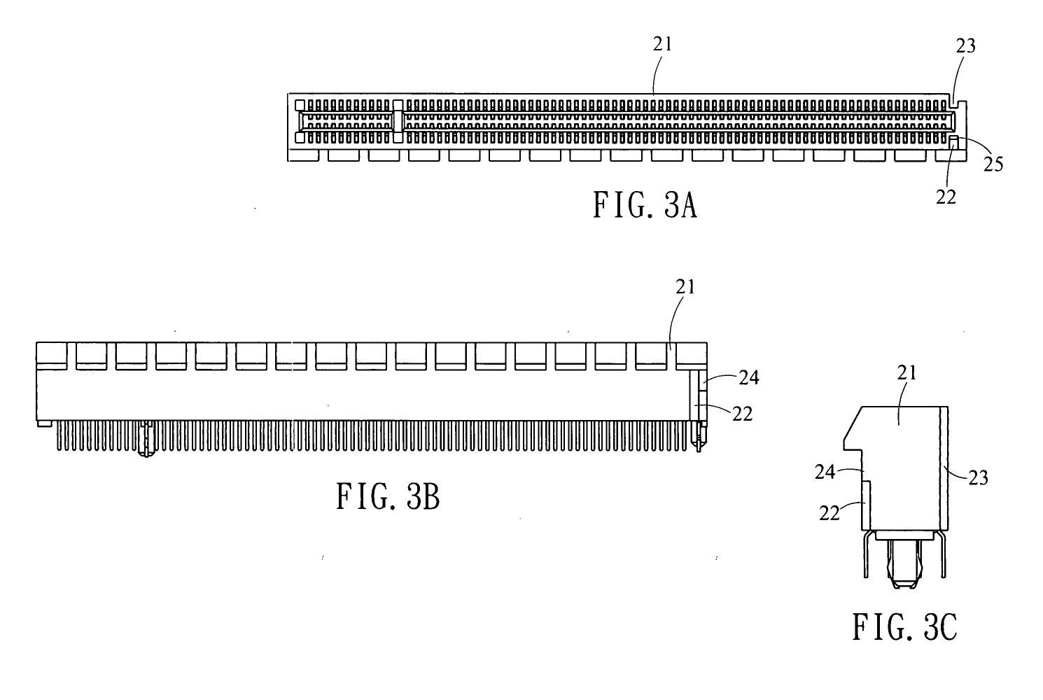

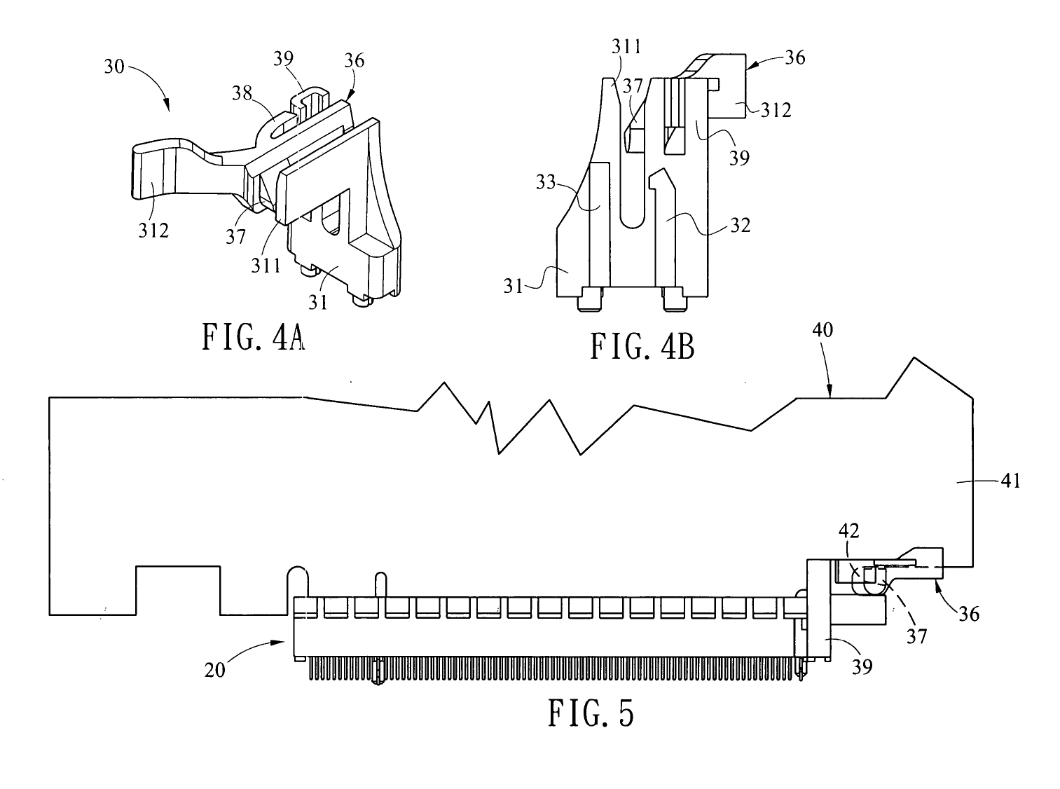

Referring to FIGS. 2 to 6B, there is shown a preferred embodiment of the invention. The invention comprises an elongated expansion slot 20 mounted on the motherboard of a microcomputer. The expansion slot 20 comprises a hollow frame 21, a projection 25 provided on an internal wall of the frame 21 at one end, a downwardly extended peg member 24 provided at one end, a first recess 22 provided at one end, and an opposite second recess 23 provided at one end. The invention further comprises a fastening mechanism 30 mounted at one end of the expansion slot 20 and comprising a first guide member 32 provided at one end, a second guide member 33 opposite the first guide member 32 provided at one end in which both the first and second guide members 32 and 33 are matingly fastened in the first and second recesses 22 and 23 respectively, a support 31 with both the first and the second guide members 32 and 33 formed thereon, a longitudinal slit 34 defined by the first and the second guide members 32 and 33 for securely receiving the peg member 24, a hook 35 provided on an inner surface of the first guide member 32 fastened at the projection 25, an upper flexible member 36, a bent member 38 extended from the flexible member 36, a latch 312 formed at an open end of the flexible member 36, an upright first stop member 39 spaced from the bent member 38, a transverse second stop member 311 parallel with the flexible member 36, and a wedge 37 formed on a side of the flexible member 36 spaced from the second stop member 311.

One end 41 of an adapter card 40 presses the oblique surface of the wedge 37 when the adapter card 40 is inserted into the assembled expansion slot 20 and the fastening mechanism 30. Thus, the flexible member 36 is flexed away from the second stop member 311 until a tip of the wedge 37 enters into a hole 42 of the adapter card 40 for fastening. At this position, the adapter card 40 is reliably secured to and electrically connected to the expansion slot 20 (see FIG. 5).

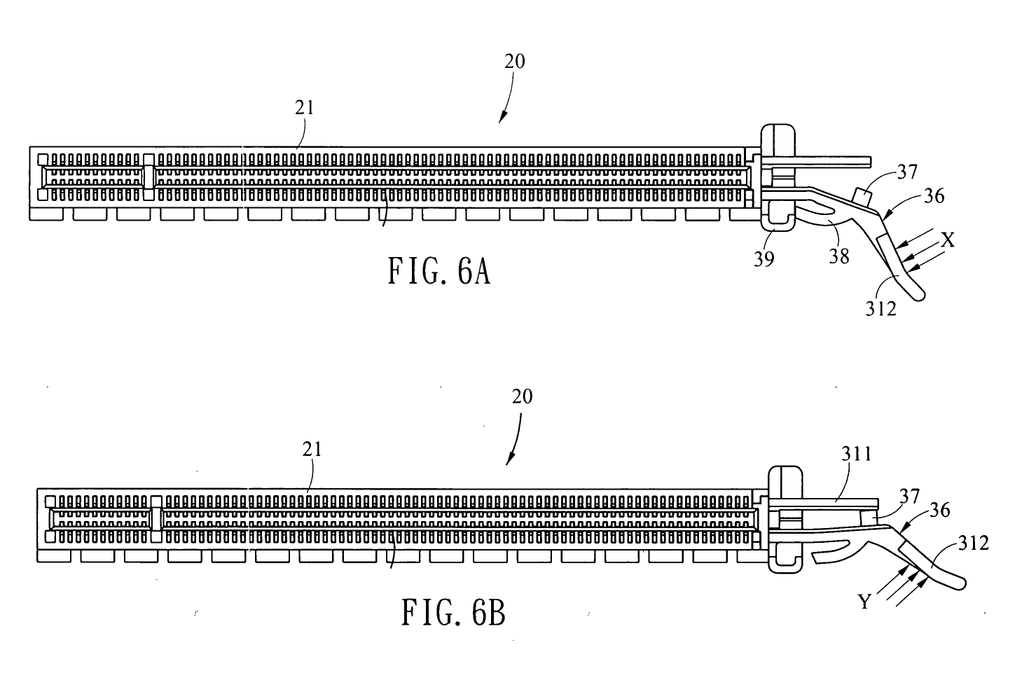

As shown in FIG. 6B, in a case that the adapter card 40 is not inserted into the expansion slot 20, an excessive flexing of the latch 312 as indicated by arrow Y will be stopped when the wedge 37 contacts the second stop member 311. As an end, the flexible member 36 is prevented from being broken.

As shown in FIG. 6A in conjunction with FIG. 5, a sufficient flexing of the latch 312 as indicated by arrow X will disengage the wedge 37 from the hole 42. Hence, it is possible of removing the adapter card 40 from the expansion slot 20 thereafter. It is important that the flexing force exerted on the latch 312 will not exceed a predetermined maximum value since the first stop member 39 serves as a stop if the bent member 38 contacts the first stop member 39. As an end, the flexible member 36 is prevented from being broken in the unfastening process.

While the invention herein disclosed has been described by means of specific embodiments, numerous modifications and variations could be made thereto by those skilled in the art without departing from the scope and spirit of the invention set forth in the claims.

What is claimed is:

1. An expansion slot mounted on a motherboard of a microcomputer for electrically coupling to an inserted adapter card, comprising:
a hollow frame;
a fastening mechanism coupled to one end of the frame and comprising a support including an upper flexible member and a protrusion formed on a side of the flexible member so as to move as the flexible member flexes such that inserting the adapter card into the frame will flex the flexible member until the protrusion enters into a hole of the adapter card for fastening; and
a stop assembly formed on the support for limiting the flexible member to flex within a predetermined angle in either direction.

2. The expansion slot of claim 1, further comprising a bent member extended from the flexible member opposite the protrusion.

3. The expansion slot of claim 1, wherein the stop assembly comprises an upright first stop member and a transverse second stop member with the flexible member disposed between the first and second stop members so as to limit the flexible member to flex in a range between the first and second stop members.

4. The expansion slot of claim 3, wherein the first stop member is spaced from the bent member and the second stop member is spaced from the protrusion such that flexing the flexible member away from the second stop member will be stopped by the first stop member or flexing the flexible member toward the second stop member will be stopped when the protrusion contacts the second stop member.

5. The expansion slot of claim 1, further comprising a positioning member disposed between the frame and the fastening mechanism, and wherein the positioning member exerts a sufficient snapping force to fasten the frame and the fastening mechanism together when the fastening mechanism is attached to the frame.

6. The expansion slot of claim 1, wherein the frame comprises a first recess provided at one end and an opposite second recess provided at one end, and the support comprises a first guide member provided in the first recess and an opposite second guide member provided in the second recess such that both the first and the second guide members are adapted to move vertically.

7. The expansion slot of claim 6, wherein the positioning member comprises a projection and a hook provided between the first guide member and the first recess.

8. The expansion slot of claim 6, further comprising a downwardly extended peg member provided between one end of the frame and the first recess for limiting an upward movement of the fastening mechanism to a predetermined distance.
